(19) United States
(12) Patent Application Publication
(10) Pub. No.: US 2016/0309619 A1
(43) Pub. Date: Oct. 20, 2016

(54) LIQUID COOLING HEAT DISSIPATION STRUCTURE AND METHOD OF MANUFACTURING THE SAME

(71) Applicant: COOLER MASTER CO., LTD., NEW TAIPEI CITY (TW)

(72) Inventors: SHUI-FA TSAI, NEW TAIPEI CITY (TW); SHIH-YI CHANG, NEW TAIPEI CITY (TW)

(21) Appl. No.: 14/689,157

(22) Filed: Apr. 17, 2015

(51) Int. Cl. H05K 7/20; B23P 15/26

(52) U.S. Cl. CPC H05K 7/20254; H05K 7/20409; H05K 7/20218; H05K 7/20272; B23P 15/26

(57) ABSTRACT

A liquid cooling heat dissipation structure includes a heat conduction module, a heat dissipation module, and a liquid supply module. The heat conduction module includes a first heat-conducting substrate contacting at least one heat-generating source and a second heat-conducting substrate disposed on the first heat-conducting substrate. The heat dissipation module is disposed on the heat conduction module. The liquid supply module is detachably disposed on the heat conduction module to cover the heat dissipation module. The liquid supply module includes an external cover body and a radial-flow centrifugal impeller detachably disposed on the external cover body. The heat conductivity coefficient and the temperature uniformity of the heat conduction module is larger than the heat conductivity coefficient and the temperature uniformity of the heat dissipation module, and the heat-dissipating area of the heat dissipation module is larger than the heat-dissipating area of the heat conduction module.

### BACKGROUND OF THE INVENTION

1. Field of the Invention

The instant disclosure relates to a heat dissipation structure and a method of manufacturing the same, and more particularly to a liquid cooling heat dissipation structure and a method of manufacturing the same.

2. Description of Related Art

Over the years, the processing velocity of CPUs has become faster, thus generating larger amounts of heat. In order to dissipate the heat from the heat source to the external world, a heat-dissipating device and a fan are usually used to help dissipate the heat. However, the fan is noisy and consumes lots of power due to its high rotational speed. It has so far proven difficult for designers to solve these problems of noise and power consumption.

In order to solve the above-mentioned question, the prior art provides a water block heat-dissipating structure including a seat body and a seal cover body. The seat body has a plurality of heat-dissipating fins formed thereon, and a bottom portion of the seat body contacting a heat-generating source. In addition, the seal cover body is used to seal and cover the seat body. The seal cover body further has a water inlet and a water outlet. When the bottom portion of the seat body contacts a heat-generating source, heat is transmitted from the heat-generating source to the heat-dissipating fins. In addition, the heat of the first heat-dissipating fins can be guided away quickly by cooling liquids that circulate between the water inlet and the water outlet.

### SUMMARY OF THE INVENTION

One aspect of the instant disclosure relates to a liquid cooling heat dissipation structure and a method of manufacturing the same.

One of the embodiments of the instant disclosure provides a liquid cooling heat dissipation structure, comprising: a heat conduction module, a heat dissipation module, and a liquid supply module. The heat conductivity coefficient and the temperature uniformity of the heat conduction module is larger than the heat conductivity coefficient and the temperature uniformity of the heat dissipation module, and the heat-dissipating area of the heat dissipation module is larger than the heat-dissipating area of the heat conduction module.

Another one of the embodiments of the instant disclosure provides a method of manufacturing a liquid cooling heat dissipation structure, comprising: providing a first heat-conducting substrate, a second heat-conducting substrate, and a plurality of heat-conducting support members, wherein the first heat-conducting substrate has a plurality of first capillary structures, and the second heat-conducting substrate has a plurality of second capillary structures; welding a second heat-conducting substrate on the first heat-conducting substrate, wherein an enclosed receiving space filled with working fluid is formed between the first heat-conducting substrate and the second heat-conducting substrate, the heat-conducting support members are connected between the first heat-conducting substrate and the second heat-conducting substrate, and all of the first capillary structures, the second capillary structures, and the heat-conducting support members are received in the enclosed receiving space; welding a heat-dissipating substrate on the second heat-conducting substrate, wherein a plurality of heat-dissipating fins is integrated on the heat-dissipating substrate; and then detachably assembling a liquid supply module on the second heat-conducting substrate to cover the heat-dissipating substrate and the heat-dissipating fins, wherein the liquid supply module includes an external cover body covering the heat-dissipating substrate and the heat-dissipating fins, a radial-flow centrifugal impeller detachably disposed on the external cover body, and a fluid-splitting board disposed inside the external cover body and disposed above the heat-dissipating fins, and the radial-flow centrifugal impeller has at least one liquid inlet and at least one liquid outlet.

Yet another one of the embodiments of the instant disclosure provides a method of manufacturing a liquid cooling heat dissipation structure, comprising: providing a first heat-conducting substrate, a second heat-conducting substrate, and a plurality of heat-conducting support members, wherein the first heat-conducting substrate has a plurality of first capillary structures, and the second heat-conducting substrate has a plurality of second capillary structures disposed on a first surface thereof; integrally forming a plurality of heat-dissipating fins on a second surface of the second heat-conducting substrate; welding a second heat-conducting substrate on the first heat-conducting substrate, wherein an enclosed receiving space filled with working fluid is formed between the first heat-conducting substrate and the second heat-conducting substrate, the heat-conducting support members are connected between the first heat-conducting substrate and the second heat-conducting substrate, and all of the first capillary structures, the second capillary structures, and the heat-conducting support members are received in the enclosed receiving space; and then detachably assembling a liquid supply module on the second heat-conducting substrate to cover the heat-dissipating fins, wherein the liquid supply module includes an external cover body covering the heat-dissipating fins, a radial-flow centrifugal impeller detachably disposed on the external cover body, and a fluid-splitting board disposed inside the external cover body and disposed above the heat-dissipating fins, and the radial-flow centrifugal impeller has at least one liquid inlet and at least one liquid outlet.

To further understand the techniques, means and effects of the instant disclosure applied for achieving the prescribed objectives, the following detailed descriptions and appended drawings are hereby referred to, such that, and through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a flowchart of the method of manufacturing a liquid cooling heat dissipation structure according to the first embodiment of the instant disclosure;

FIG. 2 shows a lateral, exploded, schematic view of the heat conduction module of the liquid cooling heat dissipation structure according to the first embodiment of the instant disclosure;

FIG. 3 shows a lateral, assembled, schematic view of the heat conduction module of the liquid cooling heat dissipation structure according to the first embodiment of the instant disclosure;

FIG. 4 shows a lateral, schematic view of the step S104a according to the first embodiment of the instant disclosure;

FIG. 5 shows a top, schematic view of the step S104a according to the first embodiment of the instant disclosure;

FIG. 6 shows a lateral, schematic view of the step S104b according to the first embodiment of the instant disclosure;

FIG. 7 shows a top, schematic view of the step S104b according to the first embodiment of the instant disclosure;

FIG. 8 shows a cross-sectional, schematic view of the step S104c according to the first embodiment of the instant disclosure;

FIG. 9 shows another cross-sectional, schematic view of the step S104c according to the first embodiment of the instant disclosure;

FIG. 10 shows a cross-sectional, schematic view of the liquid cooling heat dissipation structure according to the first embodiment of the instant disclosure;

FIG. 11 shows a top, schematic view of another heat dissipation structure according to the first embodiment of the instant disclosure;

FIG. 12 shows a flowchart of the method of manufacturing a liquid cooling heat dissipation structure according to the second embodiment of the instant disclosure;

FIG. 13 shows a lateral, schematic view of the step S202a according to the second embodiment of the instant disclosure;

FIG. 14 shows a top, schematic view of the step S202a according to the second embodiment of the instant disclosure;

FIG. 15 shows a lateral, schematic view of the step S202b according to the second embodiment of the instant disclosure;

FIG. 16 shows a top, schematic view of the step S202b according to the second embodiment of the instant disclosure;

FIG. 17 shows a cross-sectional, schematic view of the step S202c according to the second embodiment of the instant disclosure;

FIG. 18 shows another cross-sectional, schematic view of the step S202c according to the second embodiment of the instant disclosure;

FIG. 19 shows a lateral, exploded, schematic view of the heat conduction module of the liquid cooling heat dissipation structure according to the second embodiment of the instant disclosure; and

FIG. 20 shows a cross-sectional, schematic view of the liquid cooling heat dissipation structure according to the second embodiment of the instant disclosure.

### DETAILED DESCRIPTION OF THE PREFERRED EMBODIMENTS

The embodiments of “a liquid cooling heat dissipation structure and a method of manufacturing the same” of the instant disclosure are described. Other advantages and objectives of the instant disclosure can be easily understood by one skilled in the art from the disclosure. The instant disclosure can be applied in different embodiments. Various modifications and variations can be made to various details in the description for different applications without departing from the scope of the instant disclosure. The drawings of the instant disclosure are provided only for simple illustrations, but are not drawn to scale and do not reflect the actual relative dimensions. The following embodiments are provided to describe in detail the concept of the instant disclosure, and are not intended to limit the scope thereof in any way.

### First Embodiment

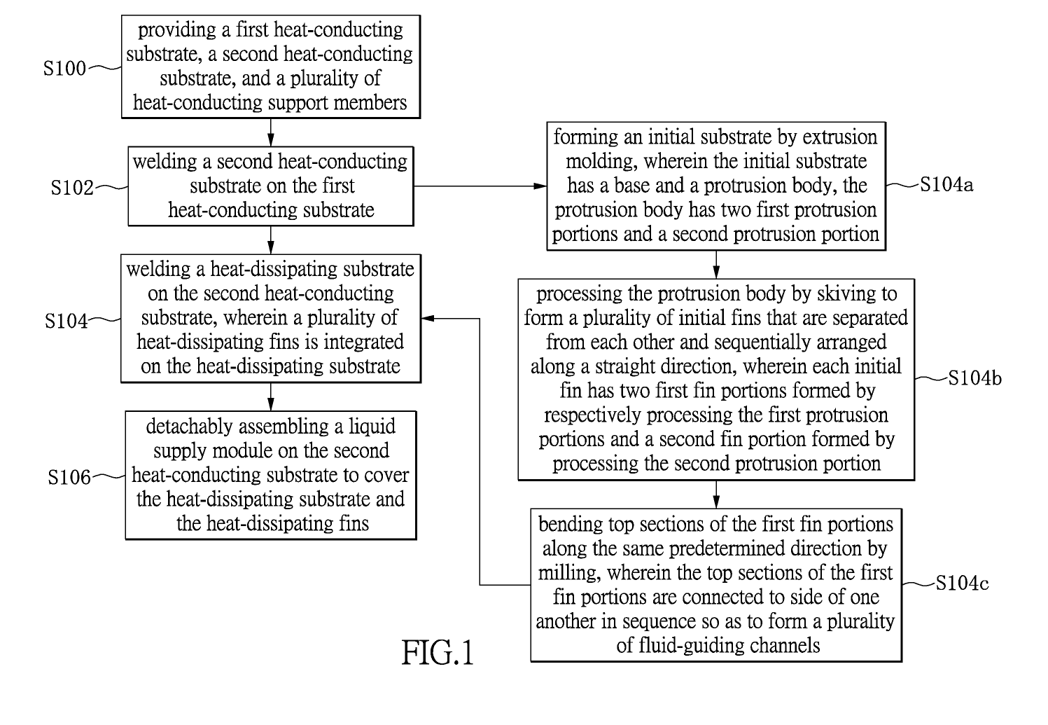

Referring to FIG. 1 to FIG. 10, the first embodiment of the instant disclosure provides a method of manufacturing a liquid cooling heat dissipation structure S, comprising the following steps:

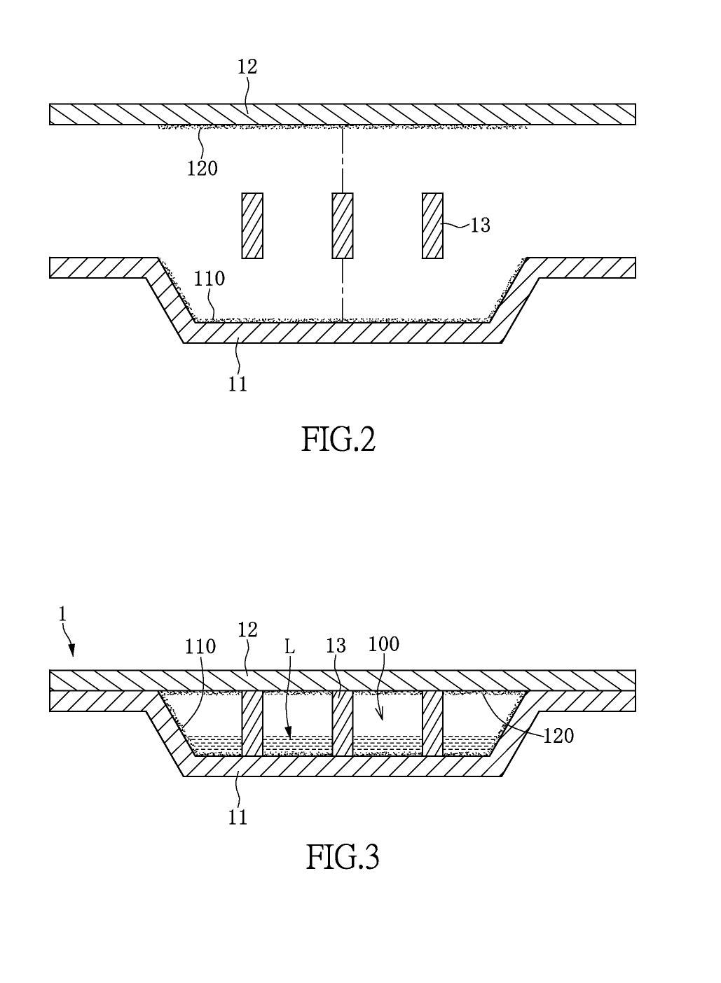

First, referring to FIG. 1 and FIG. 2, providing a first heat-conducting substrate 11, a second heat-conducting substrate 12, and a plurality of heat-conducting support members 13 (S100). More precisely, the first heat-conducting substrate 11 has a plurality of first capillary structures 110, and the second heat-conducting substrate 12 has a plurality of second capillary structures 120. For example, all of the first heat-conducting substrate 11, the second heat-conducting substrate 12, and the heat-conducting support members 13 may be made of copper material or any material with high heat conductivity coefficient.

Next, referring to FIG. 1, FIG. 2, and FIG. 3, welding a second heat-conducting substrate 12 on the first heat-conducting substrate 11 (S102). More precisely, an enclosed receiving space 100 filled with working fluid L (work liquid) is formed between the first heat-conducting substrate 11 and the second heat-conducting substrate 12, the heat-conducting support members 13 are connected between the first heat-conducting substrate 11 and the second heat-conducting substrate 12, and all of the first capillary structures 110, the second capillary structures 120, and the heat-conducting support members 13 are received in the enclosed receiving space 100. For example, the working fluid L may be selected from the group consisting of pure water, ammonia, methanol, ethanol, propane and heptane, and the enclosed receiving space 100 is filled with working fluid L with the same property or different property.

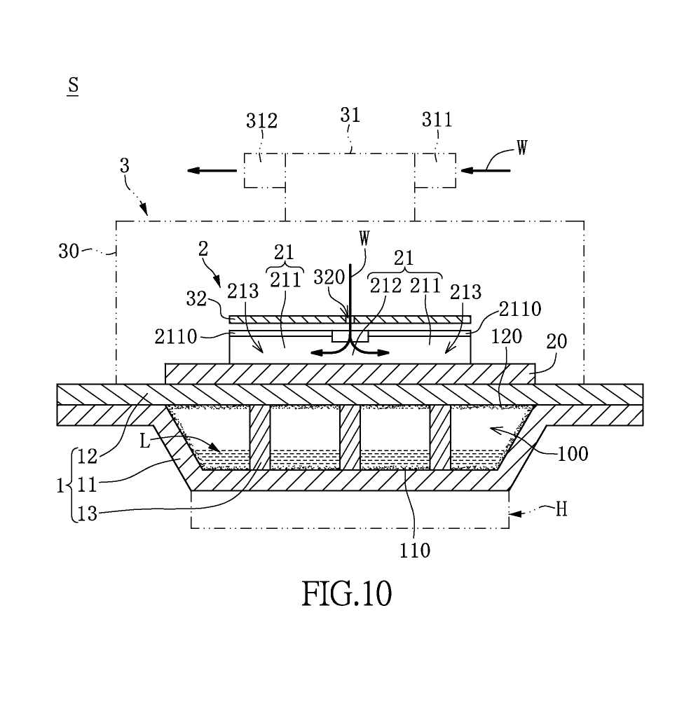

Subsequently, referring to FIG. 1, FIG. 3, and FIG. 10, welding a heat-dissipating substrate 20 on the second heat-conducting substrate 12, wherein a plurality of heat-dissipating fins 21 is integrated on the heat-dissipating substrate 20 (S104), and then detachably assembling a liquid supply module 3 on the second heat-conducting substrate 12 to cover the heat-dissipating substrate 20 and the heat-dissipating fins 21 (S106). For example, the liquid supply module 3 is detachably assembled on the second heat-conducting substrate 12 through a plurality of screws or bolts (not shown).

More precisely, before the step (S104) of welding the heat-dissipating substrate 20 on the second heat-conducting substrate 12, the method of manufacturing the liquid cooling heat dissipation structure S of the first embodiment of the instant disclosure further comprises:

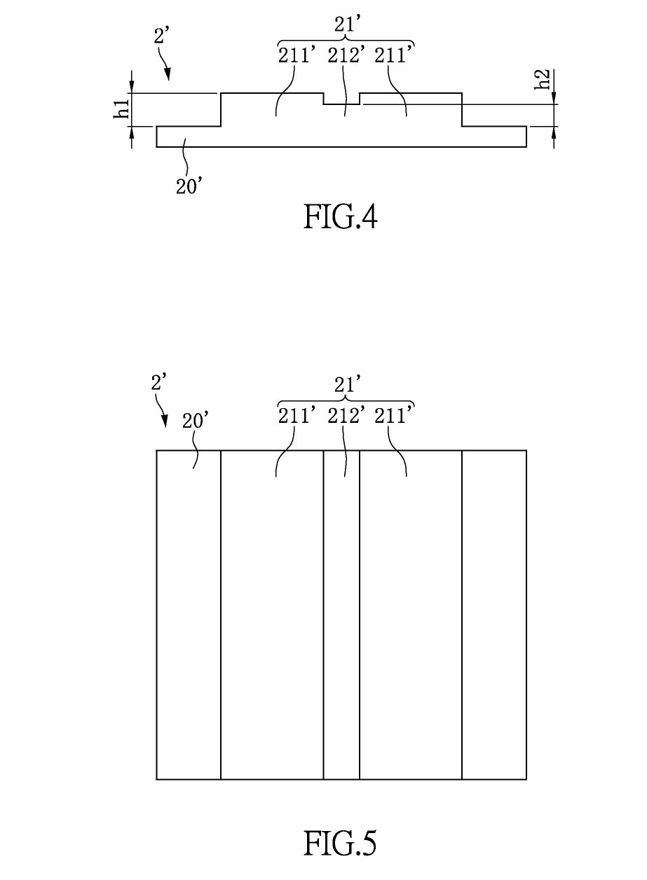

First, referring to FIG. 1, FIG. 4, and FIG. 5, forming an initial substrate 2′ by extrusion molding, wherein the initial substrate 2′ has a base 20′ and a protrusion body 21′ protruded upwardly from the base 20′, the protrusion body 21′ has two first protrusion portions 211′ protruded upwardly from the base 20′ and separated from each other and a second protrusion portion 212′ protruded upwardly from the base 20′ and connected between the two first protrusion portions 211′ (S104a). For example, a height h1 of the first protrusion portion 211′ relative to the base 20′ is larger than a height h2 of the second protrusion portion 212′ relative to the base 20′. That is to say, the distance from the top side of the first protrusion portion 211′ to the base 20′ is larger than the distance from the top side of the second protrusion portion 212′ to the base 20′.

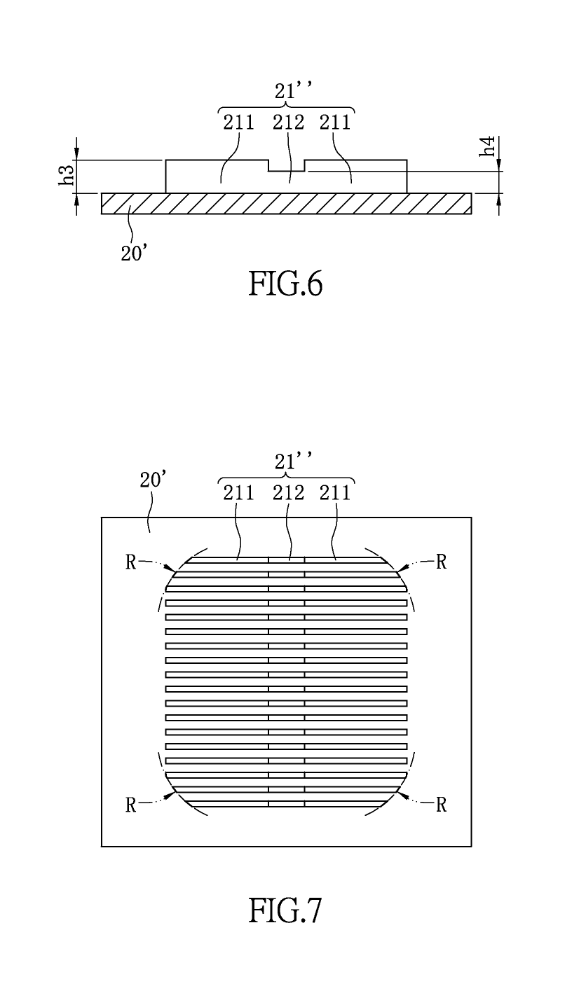

Next, referring to FIG. 1, FIG. 6, and FIG. 7, processing (manufacturing) the protrusion body 21′ by skiving to form a plurality of initial fins 21″ that are separated from each other and sequentially arranged along a straight direction, wherein each initial fin 21″ has two first fin portions 211 formed by respectively processing (manufacturing) the first protrusion portions 211′ and a second fin portion 212 formed by processing (manufacturing) the second protrusion portion 212′, and the second fin portion 212 is connected between the two first fin portions 211 (S104b). For example, a height h3 of the first fin portion 211 relative to the base 20′ is larger than a height h4 of the second fin portion 212 relative to the base 20′. That is to say, the distance from the top side of the first fin portion 211 to the base 20′ is larger than the distance from the top side of the second fin portion 212 to the base 20′.

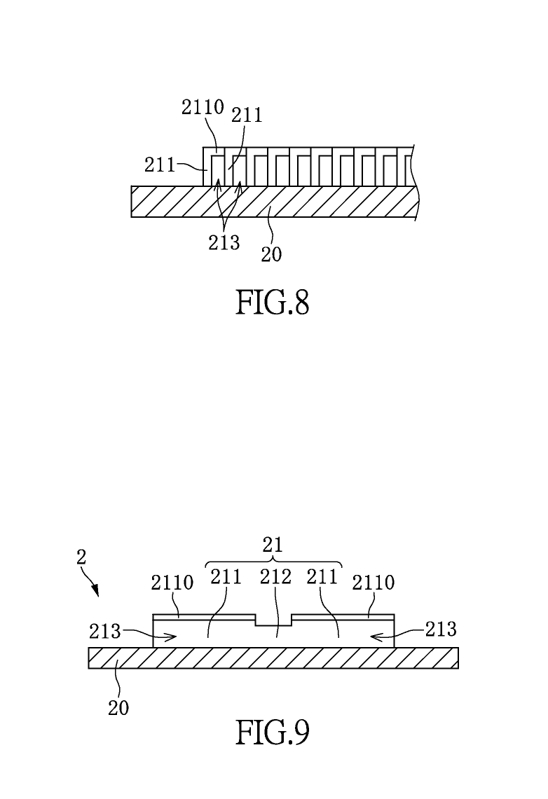

Then, referring to FIG. 1, FIG. 8, and FIG. 9, bending top sections 2110 of the first fin portions 211 along the same predetermined direction by milling, wherein the top sections 2110 of the first fin portions 211 are connected to side of one another in sequence so as to form a plurality of fluid-guiding channels (passages) 213, each fluid-guiding channel 213 is formed between the two adjacent first fin portions 211 (S104c). Therefore, each heat-dissipating fin 21 is composed of the two first fin portions 211 and the second fin portion 212 connected between the two first fin portions 211 that are bent by milling.

It is worth mentioning that as shown in FIG. 10, the first embodiment of the instant disclosure further provides a liquid cooling heat dissipation structure S, comprising: a heat conduction module 1, a heat dissipation module 2, and a liquid supply module 3. The heat conductivity coefficient and the temperature uniformity of the heat conduction module 1 is larger than the heat conductivity coefficient and the temperature uniformity of the heat dissipation module 2, and the whole heat-dissipating area (or the whole heat-dissipating efficiency, or the whole heat-dissipating coefficient) of the heat dissipation module 2 is larger than the whole heat-dissipating area of the heat conduction module 1.

First, referring to FIG. 3 and FIG. 10, the heat conduction module 1 includes a first heat-conducting substrate 11 contacting at least one heat-generating source H (such as a CPU chip or any heat-generating chip), a second heat-conducting substrate 12 disposed on the first heat-conducting substrate 11, and a plurality of heat-conducting support members 13 connected between the first heat-conducting substrate 11 and the second heat-conducting substrate 12. More precisely, the first heat-conducting substrate 11 has a plurality of first capillary structures 110, the second heat-conducting substrate 12 has a plurality of second capillary structures 120, an enclosed receiving space 100 filled with working fluid L is formed between the first heat-conducting substrate 11 and the second heat-conducting substrate 12, and all of the first capillary structures 110, the second capillary structures 120, and the heat-conducting support members 13 are received in the enclosed receiving space 100.

Moreover, referring to FIG. 9 and FIG. 10, the heat dissipation module 2 is disposed on the heat conduction module 1, and the heat dissipation module 2 includes a heat-dissipating substrate 20 disposed on the second heat-conducting substrate 12 and a plurality of heat-dissipating fins 21 integrated (integrally formed) on the heat-dissipating substrate 20. More precisely, each heat-dissipating fin 21 has two first fin portions 211 and a second fin portion 212 connected between the two first fin portions 211 that had been bent by machining. In addition, each first fin portion 211 has a top section 2110, the top sections 2110 of the first fin portions 211 of the heat-dissipating fins 21 are bent horizontally along the same predetermined direction and connected to side of one another in sequence so as to form a plurality of fluid-guiding channels 213, and each fluid-guiding channel 213 is formed between the two adjacent first fin portions 211. It is worth noting that as shown in FIG. 7, the heat-dissipating fins 21″ are arranged as a heat-dissipating fin assembly that has four arc corners R.

Furthermore, as shown in FIG. 10, the liquid supply module 3 is detachably disposed on the heat conduction module 1 to cover the heat dissipation module 2. More precisely, the liquid supply module 3 includes an external cover body 30 covering the heat dissipation module 2, a radial-flow centrifugal impeller (pump) 31 detachably disposed on the external cover body 30, and a fluid-splitting board 32 disposed inside the external cover body 30 and disposed above the heat-dissipating fins 21 of the heat dissipation module 2, and the radial-flow centrifugal impeller 31 has at least one liquid inlet 311 and at least one liquid outlet 312. Therefore, cooling liquid W passes through the at least one liquid inlet 311 and flows into the external cover body 30 by driving the radial-flow centrifugal impeller 31, and the cooling liquid W passes through a fluid-splitting opening 320 of the fluid-splitting board 32 and flows toward the second fin portions 212 and into the fluid-guiding channels 213.

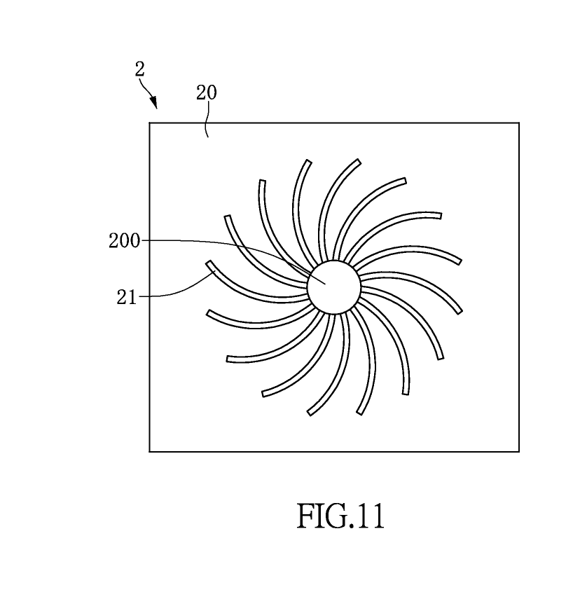

It is worth noting that as shown in FIG. 11, the instant disclosure can use another heat dissipation module 2. For example, the heat-dissipating substrate 20 includes a middle protrusion portion 200 surrounded by the heat-dissipating fins 21, the heat-dissipating fins 21 are connected with the middle protrusion portion 200 and radially arranged relative to the middle protrusion portion 200, and each heat-dissipating fin 21 has a straight shape or a curved shape as shown in FIG. 11.

### Second Embodiment

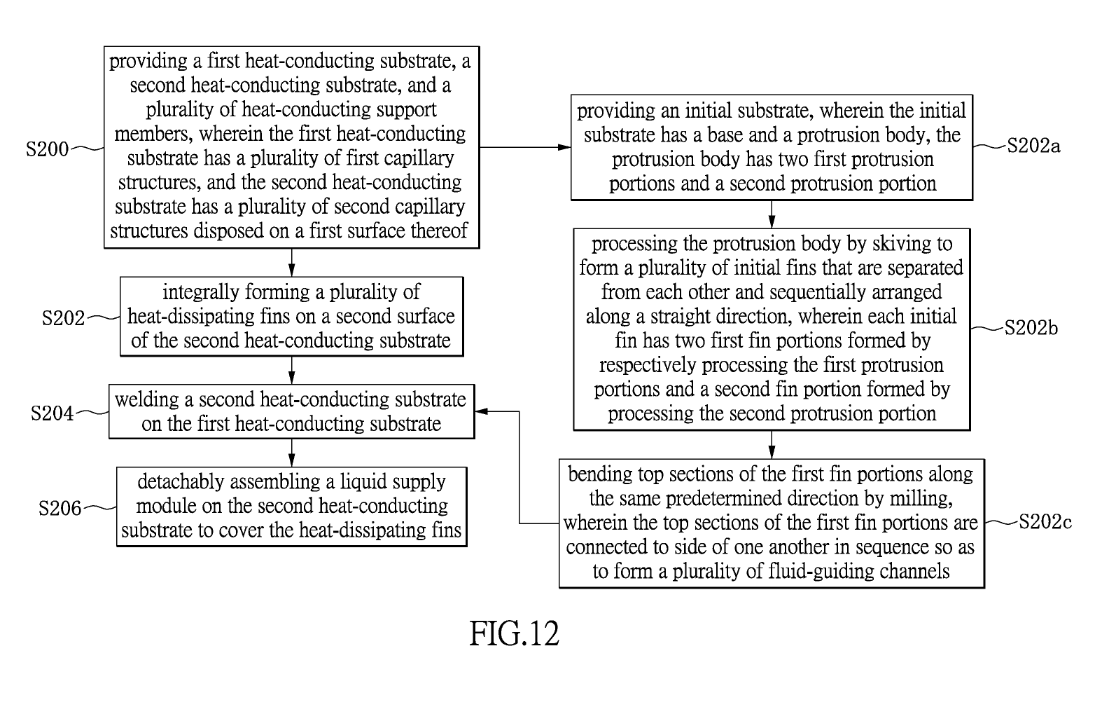

Referring to FIG. 12 to FIG. 20, the second embodiment of the instant disclosure provides a method of manufacturing a liquid cooling heat dissipation structure S, comprising the following steps:

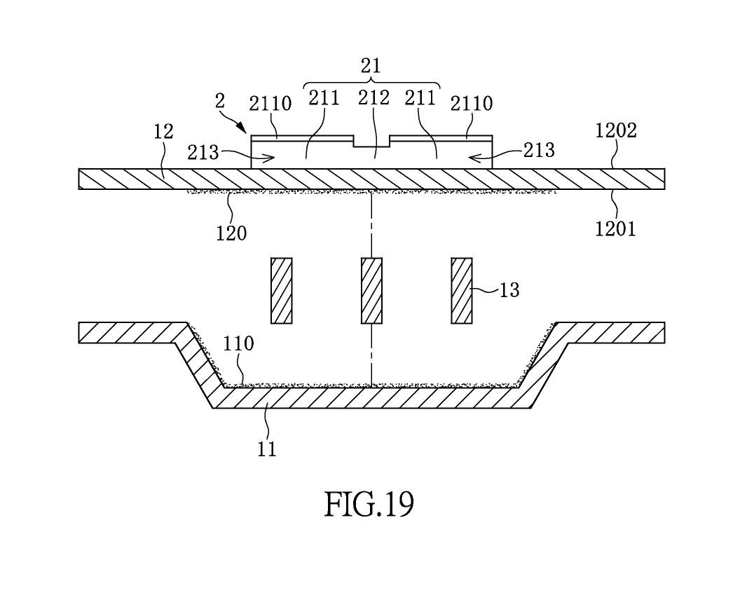

First, referring to FIG. 12 and FIG. 19, providing a first heat-conducting substrate 11, a second heat-conducting substrate 12, and a plurality of heat-conducting support members 13, wherein the first heat-conducting substrate 11 has a plurality of first capillary structures 110, and the second heat-conducting substrate 12 has a plurality of second capillary structures 120 disposed on a first surface 1201 thereof (S200); and then integrally forming a plurality of heat-dissipating fins 21 on a second surface 1202 of the second heat-conducting substrate 12 (S202).

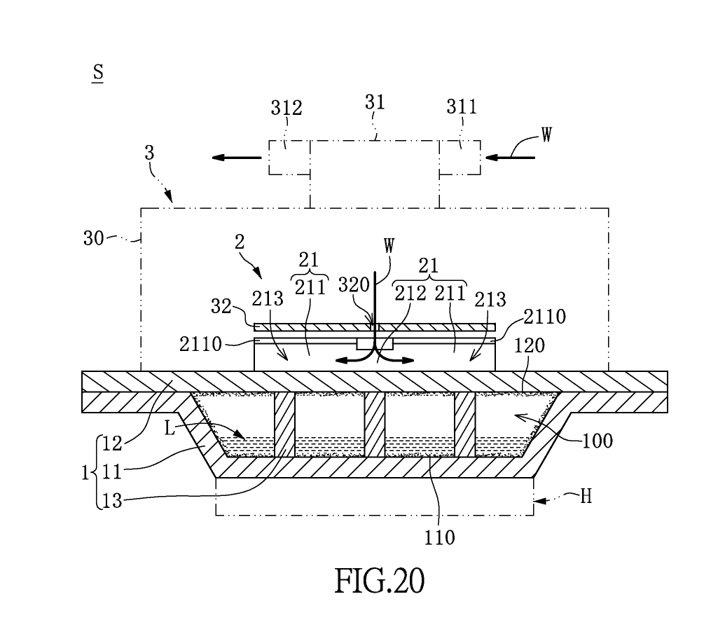

Next, referring to FIG. 12, FIG. 19, and FIG. 20, welding a second heat-conducting substrate 12 on the first heat-conducting substrate 11, wherein an enclosed receiving space 100 filled with working fluid L is formed between the first heat-conducting substrate 11 and the second heat-conducting substrate 12, the heat-conducting support members 13 are connected between the first heat-conducting substrate 11 and the second heat-conducting substrate 12, and all of the first capillary structures 110, the second capillary structures 120, and the heat-conducting support members 13 are received in the enclosed receiving space 100 (S204); and then detachably assembling a liquid supply module 3 on the second heat-conducting substrate 12 to cover the heat-dissipating fins 21 (S206). For example, the liquid supply module 3 is detachably assembled on the second heat-conducting substrate 12 through a plurality of screws or bolts (not shown).

More precisely, the step (S202) of integrally forming the plurality of heat-dissipating fins 21 on the second surface 1202 of the second heat-conducting substrate 12 further comprises the following steps:

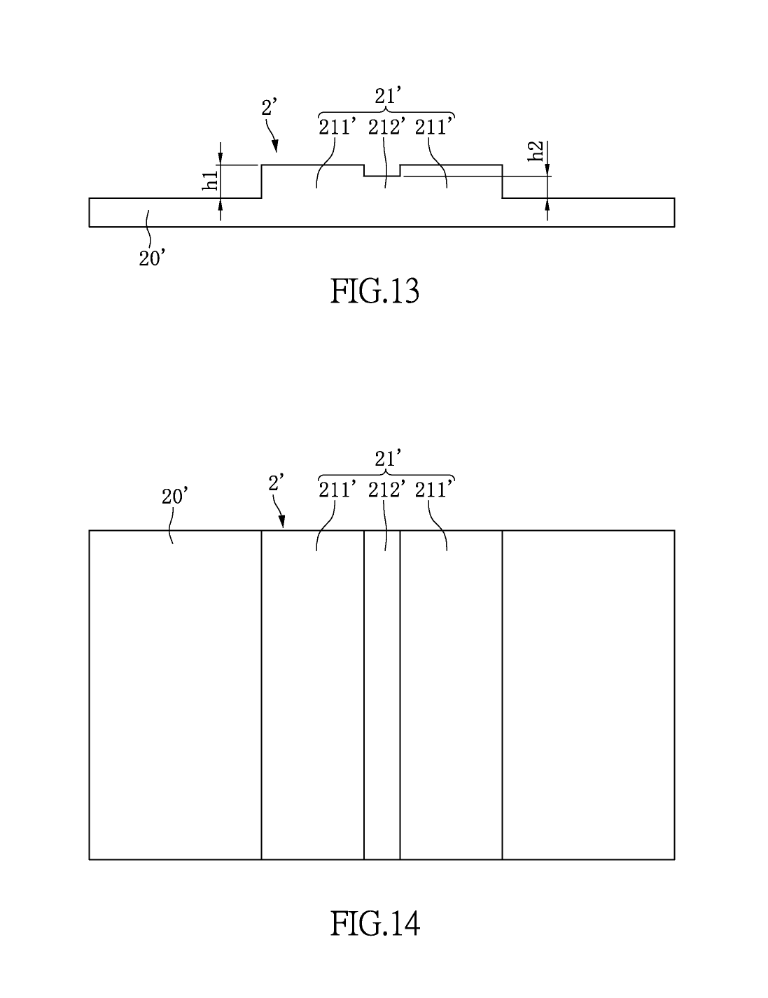

First, referring to FIG. 12, FIG. 13, and FIG. 14, providing an initial substrate 2′, wherein the initial substrate 2′ has a base 20′ (i.e., the second heat-conducting substrate 12) and a protrusion body 21′ protruded upwardly from the base 20′, the protrusion body 21′ has two first protrusion portions 211′ protruded upwardly from the base 20′ and separated from each other and a second protrusion portion 212′ protruded upwardly from the base 20′ and connected between the two first protrusion portions 211′ (S202a). For example, a height h1 of the first protrusion portion 211′ relative to the base 20′ is larger than a height h2 of the second protrusion portion 212′ relative to the base 20′. That is to say, the distance from the top side of the first protrusion portion 211′ to the base 20′ is larger than the distance from the top side of the second protrusion portion 212′ to the base 20′. It is worth noting that the base 20′ is just the second heat-conducting substrate 12, and the second capillary structures 120 can be or cannot be prefabricated on the bottom surface of the second heat-conducting substrate 12.

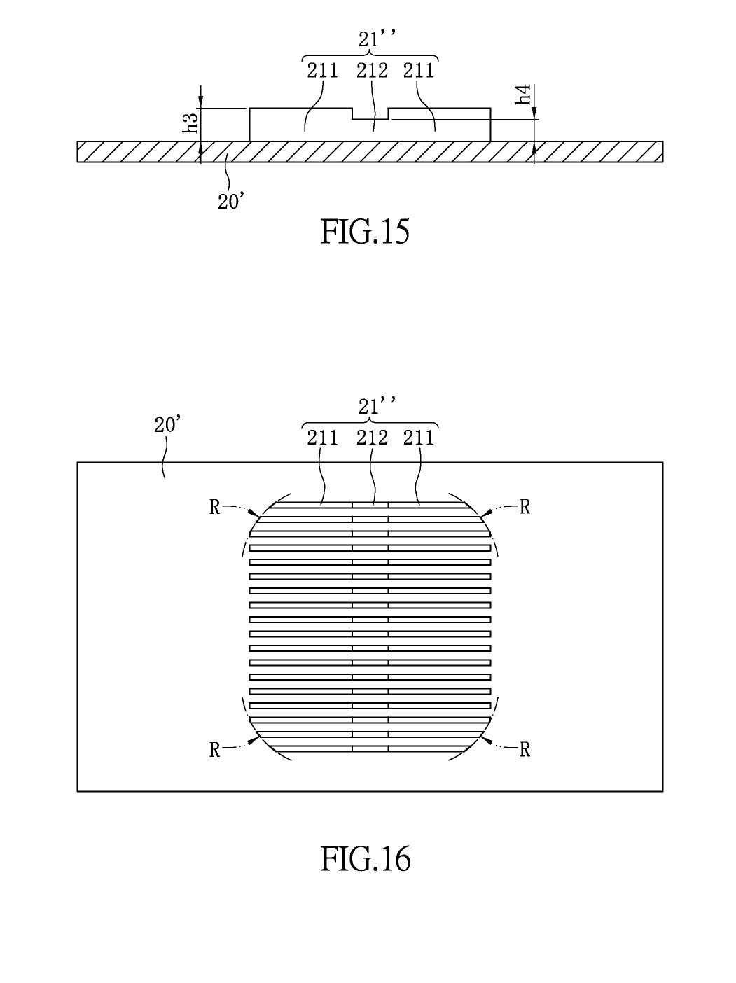

Next, referring to FIG. 12, FIG. 15, and FIG. 16, processing the protrusion body 21′ by skiving to form a plurality of initial fins 21″ that are separated from each other and sequentially arranged along a straight direction, wherein each initial fin 21″ has two first fin portions 211 formed by respectively processing the first protrusion portions 211′ and a second fin portion 212 formed by processing the second protrusion portion 212′, and the second fin portion 212 is connected between the two first fin portions 211 (S202b). For example, a height h3 of the first fin portion 211 relative to the base 20′ is larger than a height h4 of the second fin portion 212 relative to the base 20′. That is to say, the distance from the top side of the first fin portion 211 to the base 20′ is larger than the distance from the top side of the second fin portion 212 to the base 20′.

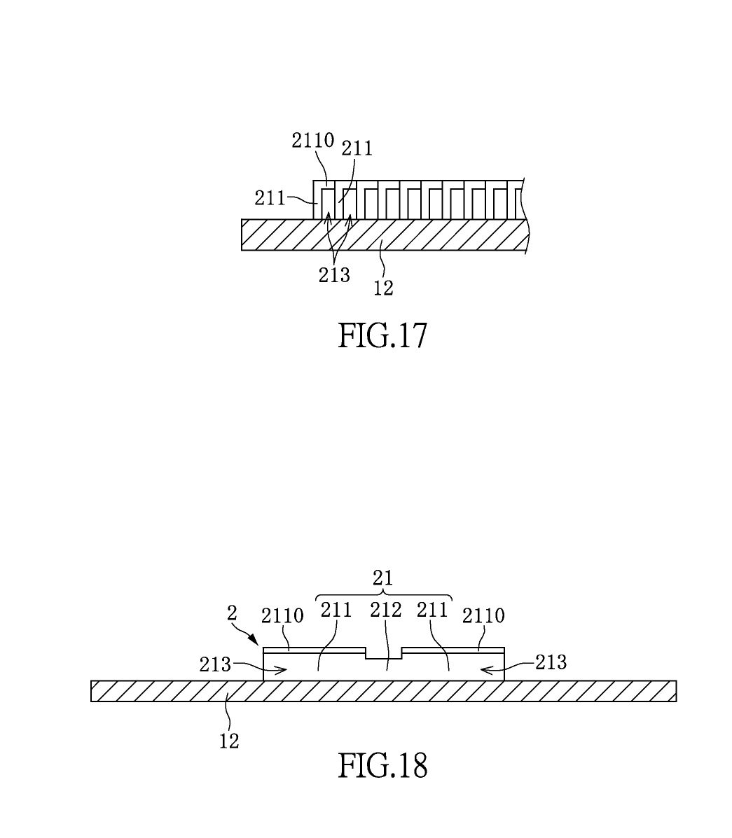

Then, referring to FIG. 12, FIG. 17, and FIG. 18, bending top sections 2110 of the first fin portions 211 along the same predetermined direction by milling, wherein the top sections 2110 of the first fin portions 211 are connected to side of one another in sequence so as to form a plurality of fluid-guiding channels 213, and each fluid-guiding channel 213 is formed between the two adjacent first fin portions 211 (S202c). Therefore, each heat-dissipating fin 21 is composed of the two first fin portions 211 and the second fin portion 212 connected between the two first fin portions 211 that are bent by milling.

It is worth mentioning that as shown in FIG. 20, the first embodiment of the instant disclosure further provides a liquid cooling heat dissipation structure S, comprising: a heat conduction module 1, a heat dissipation module 2, and a liquid supply module 3. The heat conductivity coefficient and the temperature uniformity of the heat conduction module 1 is larger than the heat conductivity coefficient and the temperature uniformity of the heat dissipation module 2, and the whole heat-dissipating area (or the whole heat-dissipating efficiency, or the whole heat-dissipating coefficient) of the heat dissipation module 2 is larger than the whole heat-dissipating area of the heat conduction module 1.

Comparing FIG. 20 with FIG. 10, the difference between the second embodiment and the first embodiment is as follows: in the second embodiment, the heat dissipation module 2 includes a plurality of heat-dissipating fins 21 integrated on the second heat-conducting substrate 12. That is to say, the second embodiment of the instant disclosure can provide a second heat-conducting substrate 12 with the plurality of heat-dissipating fins 21.

The aforementioned descriptions merely represent the preferred embodiments of the instant disclosure, without any intention to limit the scope of the instant disclosure which is fully described only within the following claims. Various equivalent changes, alterations or modifications based on the claims of the instant disclosure are all, consequently, viewed as being embraced by the scope of the instant disclosure.

What is claimed is:

1. A liquid cooling heat dissipation structure, comprising:
a heat conduction module including a first heat-conducting substrate contacting at least one heat-generating source, a second heat-conducting substrate disposed on the first heat-conducting substrate, and a plurality of heat-conducting support members connected between the first heat-conducting substrate and the second heat-conducting substrate, wherein the first heat-conducting substrate has a plurality of first capillary structures, the second heat-conducting substrate has a plurality of second capillary structures, an enclosed receiving space filled with working fluid is formed between the first heat-conducting substrate and the second heat-conducting substrate, and all of the first capillary structures, the second capillary structures, and the heat-conducting support members are received in the enclosed receiving space;
a heat dissipation module disposed on the heat conduction module; and
a liquid supply module detachably disposed on the heat conduction module to cover the heat dissipation module, wherein the liquid supply module includes an external cover body covering the heat dissipation module, a radial-flow centrifugal impeller detachably disposed on the external cover body, and a fluid-splitting board disposed inside the external cover body and disposed above the heat dissipation module, and the radial-flow centrifugal impeller has at least one liquid inlet and at least one liquid outlet;
wherein the heat conductivity coefficient and the temperature uniformity of the heat conduction module is larger than the heat conductivity coefficient and the temperature uniformity of the heat dissipation module, and the heat-dissipating area of the heat dissipation module is larger than the heat-dissipating area of the heat conduction module.

2. The liquid cooling heat dissipation structure of claim 1, wherein the heat dissipation module includes a heat-dissipating substrate disposed on the second heat-conducting substrate and a plurality of heat-dissipating fins integrated on the heat-dissipating substrate, and the heat-dissipating fins are arranged as a heat-dissipating fin assembly having four arc corners.

3. The liquid cooling heat dissipation structure of claim 2, wherein each heat-dissipating fin has two first fin portions and a second fin portion connected between the two first fin portions, each first fin portion has a top section, the top sections of the first fin portions of the heat-dissipating fins are bent horizontally along the same predetermined direction and connected to side of one another in sequence so as to form a plurality of fluid-guiding channels, and each fluid-guiding channel is formed between the two adjacent first fin portions.

4. The liquid cooling heat dissipation structure of claim 3, wherein cooling liquid passes through the at least one liquid inlet and flows into the external cover body by driving the radial-flow centrifugal impeller, and the cooling liquid passes through a fluid-splitting opening of the fluid-splitting board and flows toward the second fin portions and into the fluid-guiding channels.

5. The liquid cooling heat dissipation structure of claim 1, wherein the heat dissipation module includes a plurality of heat-dissipating fins integrated on the second heat-conducting substrate, and the heat-dissipating fins are arranged as a heat-dissipating fin assembly having four arc corners.

6. The liquid cooling heat dissipation structure of claim 5, wherein each heat-dissipating fin has two first fin portions and a second fin portion connected between the two first fin portions, each first fin portion has a top section, the top sections of the first fin portions of the heat-dissipating fins are bent horizontally along the same predetermined direction and connected to side of one another in sequence so as to form a plurality of fluid-guiding channels, and each fluid-guiding channel is formed between the two adjacent first fin portions.

7. The liquid cooling heat dissipation structure of claim 6, wherein cooling liquid passes through the at least one liquid inlet and flows into the external cover body by driving the radial-flow centrifugal impeller, and the cooling liquid passes through a fluid-splitting opening of the fluid-splitting board and flows toward the second fin portions and into the fluid-guiding channels.

8. The liquid cooling heat dissipation structure of claim 1, wherein the heat-dissipating substrate includes a middle protrusion portion surrounded by the heat-dissipating fins, the heat-dissipating fins are connected with the middle protrusion portion and radially arranged relative to the middle protrusion portion, and each heat-dissipating fin has a straight shape or a curved shape.

9. A method of manufacturing a liquid cooling heat dissipation structure, comprising:
providing a first heat-conducting substrate, a second heat-conducting substrate, and a plurality of heat-conducting support members, wherein the first heat-conducting substrate has a plurality of first capillary structures, and the second heat-conducting substrate has a plurality of second capillary structures;
welding a second heat-conducting substrate on the first heat-conducting substrate, wherein an enclosed receiving space filled with working fluid is formed between the first heat-conducting substrate and the second heat-conducting substrate, the heat-conducting support members are connected between the first heat-conducting substrate and the second heat-conducting substrate, and all of the first capillary structures, the second capillary structures, and the heat-conducting support members are received in the enclosed receiving space;
welding a heat-dissipating substrate on the second heat-conducting substrate, wherein a plurality of heat-dissipating fins is integrated on the heat-dissipating substrate; and
detachably assembling a liquid supply module on the second heat-conducting substrate to cover the heat-dissipating substrate and the heat-dissipating fins, wherein the liquid supply module includes an external cover body covering the heat-dissipating substrate and the heat-dissipating fins, a radial-flow centrifugal impeller detachably disposed on the external cover body, and a fluid-splitting board disposed inside the external cover body and disposed above the heat-dissipating fins, and the radial-flow centrifugal impeller has at least one liquid inlet and at least one liquid outlet.

10. The method of claim 9, wherein before the step of welding the heat-dissipating substrate on the second heat-conducting substrate, the method further comprises:
forming an initial substrate by extrusion molding, wherein the initial substrate has a base and a protrusion body protruded upwardly from the base, the protrusion body has two first protrusion portions protruded upwardly from the base and separated from each other and a second protrusion portion protruded upwardly from the base and connected between the two first protrusion portions, and a height of the first protrusion portion relative to the base is larger than a height of the second protrusion portion relative to the base;
processing the protrusion body by skiving to form a plurality of initial fins that are separated from each other and sequentially arranged along a straight direction, wherein each initial fin has two first fin portions formed by respectively processing the first protrusion portions and a second fin portion formed by processing the second protrusion portion, the second fin portion is connected between the two first fin portions, and a height of the first fin portion relative to the base is larger than a height of the second fin portion relative to the base; and
bending top sections of the first fin portions along the same predetermined direction by milling, wherein the top sections of the first fin portions are connected to side of one another in sequence so as to form a plurality of fluid-guiding channels, each fluid-guiding channel is formed between the two adjacent first fin portions, and each heat-dissipating fin is composed of the two first fin portions and the second fin portion connected between the two first fin portions.

11. The method of claim 10, wherein cooling liquid passes through the at least one liquid inlet and flows into the external cover body by driving the radial-flow centrifugal impeller, and the cooling liquid passes through a fluid-splitting opening of the fluid-splitting board and flows toward the second fin portions and into the fluid-guiding channels.

12. The method of claim 9, wherein the heat-dissipating substrate includes a middle protrusion portion surrounded by the heat-dissipating fins, the heat-dissipating fins are connected with the middle protrusion portion and radially arranged relative to the middle protrusion portion, and each heat-dissipating fin has a straight shape or a curved shape.

13. The method of claim 9, wherein the heat-dissipating fins are arranged as a heat-dissipating fin assembly having four arc corners.

14. The method of claim 9, wherein the liquid cooling heat dissipation structure comprises:
a heat conduction module including the first heat-conducting substrate contacting at least one heat-generating source, the second heat-conducting substrate disposed on the first heat-conducting substrate, and the plurality of heat-conducting support members connected between the first heat-conducting substrate and the second heat-conducting substrate;
a heat dissipation module disposed on the heat conduction module, wherein the heat dissipation module includes the heat-dissipating substrate and the plurality of heat-dissipating fins; and
the liquid supply module detachably disposed on the heat conduction module to cover the heat dissipation module;
wherein the heat conductivity coefficient and the temperature uniformity of the heat conduction module is larger than the heat conductivity coefficient and the temperature uniformity of the heat dissipation module, and the heat-dissipating area of the heat dissipation module is larger than the heat-dissipating area of the heat conduction module.

15. A method of manufacturing a liquid cooling heat dissipation structure, comprising:
providing a first heat-conducting substrate, a second heat-conducting substrate, and a plurality of heat-conducting support members, wherein the first heat-conducting substrate has a plurality of first capillary structures, and the second heat-conducting substrate has a plurality of second capillary structures disposed on a first surface thereof;
integrally forming a plurality of heat-dissipating fins on a second surface of the second heat-conducting substrate;
welding a second heat-conducting substrate on the first heat-conducting substrate, wherein an enclosed receiving space filled with working fluid is formed between the first heat-conducting substrate and the second heat-conducting substrate, the heat-conducting support members are connected between the first heat-conducting substrate and the second heat-conducting substrate, and all of the first capillary structures, the second capillary structures, and the heat-conducting support members are received in the enclosed receiving space; and
detachably assembling a liquid supply module on the second heat-conducting substrate to cover the heat-dissipating fins, wherein the liquid supply module includes an external cover body covering the heat-dissipating fins, a radial-flow centrifugal impeller detachably disposed on the external cover body, and a fluid-splitting board disposed inside the external cover body and disposed above the heat-dissipating fins, and the radial-flow centrifugal impeller has at least one liquid inlet and at least one liquid outlet.

16. The method of claim 15, wherein the step of integrally forming the plurality of heat-dissipating fins on the second surface of the second heat-conducting substrate further comprises:
providing an initial substrate, wherein the initial substrate has a base and a protrusion body protruded upwardly from the base, the protrusion body has two first protrusion portions protruded upwardly from the base and separated from each other and a second protrusion portion protruded upwardly from the base and connected between the two first protrusion portions, and a height of the first protrusion portion relative to the base is larger than a height of the second protrusion portion relative to the base;
processing the protrusion body by skiving to form a plurality of initial fins that are separated from each other and sequentially arranged along a straight direction, wherein each initial fin has two first fin portions formed by respectively processing the first protrusion portions and a second fin portion formed by processing the second protrusion portion, the second fin portion is connected between the two first fin portions, and a height of the first fin portion relative to the base is larger than a height of the second fin portion relative to the base; and
bending top sections of the first fin portions along the same predetermined direction by milling, wherein the top sections of the first fin portions are connected to side of one another in sequence so as to form a plurality of fluid-guiding channels, each fluid-guiding channel is formed between the two adjacent first fin portions, and each heat-dissipating fin is composed of the two first fin portions and the second fin portion connected between the two first fin portions.

17. The method of claim 16, wherein cooling liquid passes through the at least one liquid inlet and flows into the external cover body by driving the radial-flow centrifugal impeller, and the cooling liquid passes through a fluid-splitting opening of the fluid-splitting board and flows toward the second fin portions and into the fluid-guiding channels.

18. The method of claim 15, wherein the heat-dissipating fins are arranged as a heat-dissipating fin assembly having four arc corners.

19. The method of claim 15 wherein the second heat-conducting substrate includes a middle protrusion portion surrounded by the heat-dissipating fins, the heat-dissipating fins are connected with the middle protrusion portion and radially arranged relative to the middle protrusion portion, and each heat-dissipating fin has a straight shape or a curved shape.

20. The method of claim 15, wherein the liquid cooling heat dissipation structure comprises:
a heat conduction module including the first heat-conducting substrate contacting at least one heat-generating source, the second heat-conducting substrate disposed on the first heat-conducting substrate, and the plurality of heat-conducting support members connected between the first heat-conducting substrate and the second heat-conducting substrate;
a heat dissipation module including the plurality of heat-dissipating fins integrated on the second heat-conducting substrate; and
the liquid supply module detachably disposed on the heat conduction module to cover the heat dissipation module;
wherein the heat conductivity coefficient and the temperature uniformity of the heat conduction module is larger than the heat conductivity coefficient and the temperature uniformity of the heat dissipation module, and the heat-dissipating area of the heat dissipation module is larger than the heat-dissipating area of the heat conduction module.
